(19) United States
(12) Patent Application Publication
(10) Pub. No.: US 2020/0198114 A1
(43) Pub. Date: Jun. 25, 2020

(54) ELECTRIC WORKING MACHINE

(71) Applicant: MAKITA CORPORATION, Anjo-shi, Aichi (JP)

(72) Inventor: Hitoshi SUZUKI, Anjo-shi (JP)

(73) Assignee: MAKITA CORPORATION, Anjo-shi, Aichi (JP)

(21) Appl. No.: 16/318,077

(22) PCT Filed: Jul. 4, 2017
(86) PCT No.: PCT/JP2017/024506

§ 371 Date: Jan. 15, 2019

(30) Foreign Application Priority Data
Jul. 20, 2016 (JP) 2016-142584

(51) Int. Cl. B25F 5/00; B24B 23/02; H02K 11/33; H02K 7/14; H05K 7/20; H01L 23/367

(52) U.S. Cl. CPC B25F 5/008; B24B 23/028; H01L 23/367; H02K 7/145; H05K 7/20436; H02K 11/33

(57) ABSTRACT

An electric working machine in one aspect of the present disclosure includes an electronic component that emits heat, and a metal plate thermally coupled to the electronic component. A graphite sheet with high thermal conductivity is adhered to a surface of the metal plate opposite to a surface thermally coupled to the electronic component.

### CROSS-REFERENCE TO RELATED APPLICATION

This international application claims the benefit of Japanese Patent Application No. 2016-142584 filed Jul. 20, 2016 in the Japan Patent Office, and the entire disclosure of Japanese Patent Application No. 2016-142584 is incorporated herein by reference.

### TECHNICAL FIELD

The present disclosure relates to an electric working machine.

### BACKGROUND ART

Patent Document 1 below discloses an electric tool in which a FET and a heat dissipation case are coupled in a heat exchangeable manner, so that heat generated in the FET is dissipated by the heat dissipation case. FET is an abbreviation for a field effect transistor.

### PRIOR ART DOCUMENTS

### Patent Documents

Patent Document 1: Japanese Unexamined Patent Application Publication No. 2016-22543

### SUMMARY OF THE INVENTION

### Problems to be Solved by the Invention

In the technique disclosed in Patent Document 1, even if the heat dissipation case is made of metal, thermal conductivity of metal is about several hundreds [W/(m·K)]. Therefore, it is difficult for heat to be transferred to the entire heat dissipation case even if the heat dissipation case is large. Efficient heat dissipation cannot be achieved by the technique disclosed in Patent Document 1.

In one aspect of the present disclosure, it is desirable to improve heat dissipation effect of an electronic component that generates heat in an electric working machine.

### Means for Solving the Problems

An electric working machine in one aspect of the present disclosure includes an electronic component that emits heat, a metal plate thermally coupled to the electronic component, and a graphite sheet. The graphite sheet is adhered to a specific surface which is a surface opposite to a surface of the metal plate thermally coupled to the electronic component. The graphite sheet has much higher thermal conductivity than metal.

In the electric working machine as above, heat transferred from the electronic component to the metal plate is quickly transferred to a wide range of the metal plate by the graphite sheet adhered to the specific surface of the metal plate. Therefore, heat dissipation effect of the electronic component by the metal plate is improved. Heat dissipation effect of the electronic component is an effect of radiating heat emitted by the electronic component. Hereinafter, heat dissipation effect of the electronic component is simply referred to as heat dissipation effect. In addition, high heat radiation ability of the graphite sheet further improves heat dissipation effect. Therefore, if the same amount of heat is released, then the metal plate provided with the graphite sheet can have small thickness and area. As a result, it becomes easy to downsize the electric working machine.

The graphite sheet may be adhered to the specific surface so that at least one adhering part adhered to the specific surface of the metal plate and at least one non-adhering part away from the specific surface appear alternately in a specified direction. According to the electric working machine configured as above, heat dissipation effect can be further improved since area of contact between the graphite sheet and the air can be increased.

Each of the at least one non-adhering part, together with the specific surface of the metal plate, may form a tubular portion through which the air is passable. According to the electric working machine configured as above, the area of contact between the graphite sheet and the air can be further increased.

The metal plate may be provided such that a longitudinal direction of each of the at least one non-adhering part of the graphite sheet is perpendicular to the ground. According to the electric working machine configured as above, since the air flows along the at least one non-adhering part due to natural convection, heat dissipation effect can be improved. Also, if a tubular portion is formed, then the air passes through the tubular portion due to natural convection. Thus, heat dissipation effect can be further improved. Note that the term ‘perpendicular’ herein is not limited to ‘perpendicular’ in a strict sense, and may not be strictly ‘perpendicular’ as long as the same effect as above is produced.

A blower that blows wind to the graphite sheet may be further provided. According to the electric working machine configured as above, heat dissipation effect can be further improved.

In case that the at least one adhering part and the at least one non-adhering part of the graphite sheet alternately appear and a blower is also provided, the at least one non-adhering part in the graphite sheet may have a larger height from the specific surface, as the at least one non-adhering part is farther from the blower. According to the electric working machine configured as above, for example, not only a non-adhering part close to the blower but also a non-adhering part away from the blower, of a plurality of non-adhering parts, can receive wind well. The heat dissipation effect can be further improved.

The blower may be configured to generate wind by a piezoelectric element. According to the electric working machine configured as above, power consumption in the blower can be reduced. Also, the blower can have strong resistance against vibration of the electric working machine.

The metal plate thermally coupled to the electronic component may be a first metal plate. The graphite sheet may be adhered to the first metal plate, and a second metal plate which is a metal plate different from the first metal plate, in a manner to extend over the both plates. According to the electric working machine configured as above, heat from the electronic component can be transferred from the first metal plate to the second metal plate via the graphite sheet. Therefore, heat dissipation effect can be further improved.

An electric working machine in another aspect of the present disclosure includes an electronic component that emits heat, a metal plate, and a heat conduction member. The heat conduction member is provided between the electronic component and the metal plate, and transmits heat from the electronic component to the metal plate. Further, the heat conduction member includes a compressible deformable object, and a graphite sheet wrapped around the object.

In the electric working machine configured as above, heat from the electronic component is efficiently transferred to the metal plate via the graphite sheet which forms the heat conduction member. Therefore, heat dissipation effect of the electronic component can be improved. Also, the heat conduction member is formed by wrapping the compressible deformable object with the graphite sheet. Therefore, the heat conduction member, that is, an outer shape of the graphite sheet can be compressed and deformed. Thus, this heat conduction member can thermally couple the electronic component and the metal plate while absorbing error in spacing between the electronic component and the metal plate.

As a comparative example, for example, in case a thermally conductive resin is used as the heat conduction member, the resin has remarkably lower thermal conductivity than metal. Heat from the electronic component cannot be efficiently transferred to the metal plate. Therefore, heat dissipation effect of the electronic component is lowered. On the other hand, the graphite sheet has much higher thermal conductivity than metal. Therefore, heat from the electronic component can be efficiently transferred to the metal plate. As a result, heat dissipation effect of the electronic component can be enhanced.

### BRIEF DESCRIPTION OF THE DRAWINGS

FIG. 1 is a perspective view of a grinder with a battery pack.

FIG. 2 is a schematic diagram explaining a heat dissipation structure of an electronic component in the grinder of a first embodiment.

FIG. 3 is a schematic diagram explaining a heat dissipation structure of the electronic component in the grinder of a second embodiment.

FIG. 4 is a schematic perspective view explaining the heat dissipation structure of the electronic component in the grinder of the second embodiment.

FIG. 5 is a schematic perspective view explaining a heat dissipation structure of the electronic component in the grinder of a third embodiment.

FIG. 6 is a schematic perspective view explaining a heat dissipation structure of the electronic component in the grinder of a fourth embodiment.

FIG. 7 is a schematic perspective view explaining a heat dissipation structure of the electronic component in the grinder of a fifth embodiment.

FIG. 8 is a schematic diagram explaining a heat dissipation structure of the electronic component in the grinder of a sixth embodiment.

FIG. 9 is a schematic perspective view explaining the heat dissipation structure of the electronic component in the grinder of the sixth embodiment.

FIG. 10 is a schematic diagram explaining a heat dissipation structure of the electronic component in the grinder of a seventh embodiment.

FIG. 11 is a schematic diagram explaining a variation.

### EXPLANATION OF REFERENCE NUMERALS

1 . . . grinder, 2 . . . main body, 5 . . . housing, 6 . . . end work tool, 7 . . . cover, 8 . . . operation switch, 9 . . . battery attachment portion, 11 . . . motor, 13 . . . controller, 21 . . . PCB, 23 . . . electronic component, 23a . . . surface, 25 . . . metal plate, 25b . . . specific surface, 26 . . . metal plate, 27 . . . graphite sheet, 27a . . . adhering part, 27b . . . non-adhering part, 29 . . . tubular portion, 31 . . . blower, 33 . . . air blowing port, 41 . . . heat conduction member, 43 . . . object, 45 . . . graphite sheet, 50 . . . battery pack

### MODE FOR CARRYING OUT THE INVENTION

Hereinafter, example embodiments of the present disclosure will be described with reference to the drawings. In the embodiments below, a grinder will be described as an example of an electric working machine. The grinder is an electric working machine which can process a workpiece by grinding, polishing, cutting, etc.

### 1. First Embodiment

[1-1. Overall Configuration of Grinder]

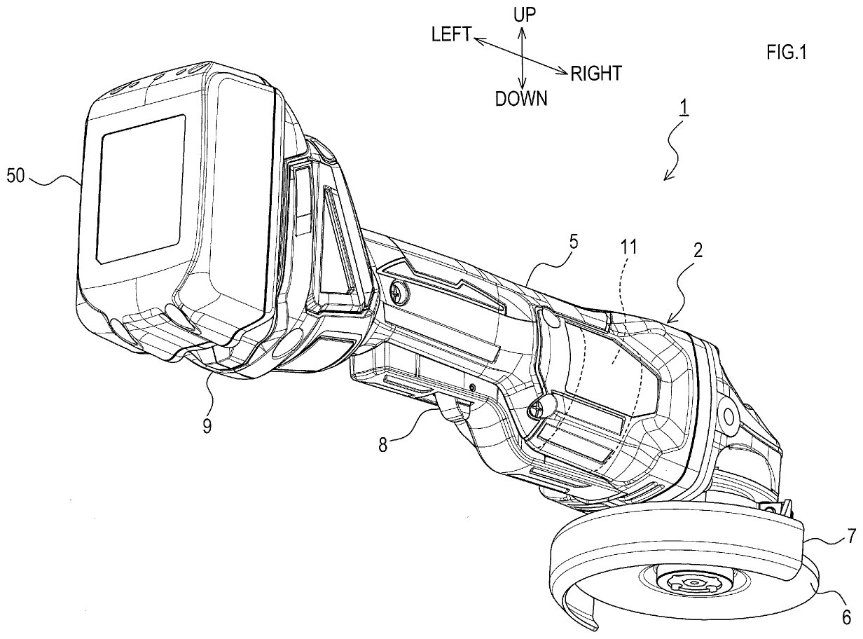

As shown in FIG. 1, a grinder 1 includes a main body 2 and a battery pack 50. The main body 2 includes a housing 5, an end work tool 6, a cover 7, and an operation switch 8.

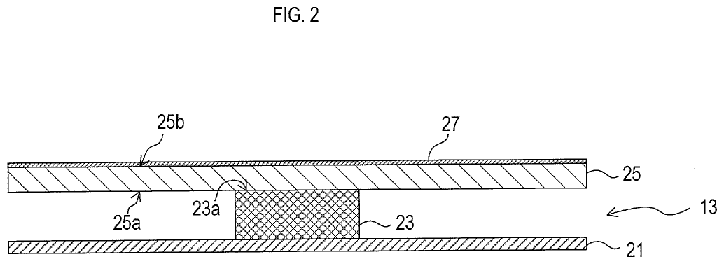

The housing 5 forms a casing of the grinder 1. The housing 5 is made of resin. The housing 5 accommodates therein a motor 11, and a controller 13 shown in FIG. 2. The motor 11 is a power source of the grinder 1. The motor 11 is arranged on a leading end side (that is, a right side in FIG. 1) in the housing 5. The motor 11 is, for example, a brushless motor, but may be a different type of motor. The controller 13 mainly controls the motor 11. The controller 13 is arranged, for example, on a rear end side (that is, a left side in FIG. 1) in the housing 5.

A battery attachment portion 9 for attachment of the battery pack 50 is provided on a side surface on the rear end side of the housing 5. The battery pack 50 is configured to be attachable/detachable to/from the battery attachment portion 9. Although not shown, the battery pack 50 accommodates a plurality of batteries.

As shown in FIG. 1, when the battery pack 50 is attached to the main body 2, electric power can be supplied from the battery pack 50 to the main body 2. Each electric load such as the motor 11 and the controller 13 in the main body 2 is adapted to operate by the electric power supplied from the battery pack 50.

The end work tool 6 is brought into direct contact with a workpiece by a user of the grinder 1 to process the workpiece. The end work tool 6 is rotationally driven by the motor 11. Examples of the end work tool 6 are, for example, a grinding wheel, a cutting wheel, a wire brush, and the like.

The cover 7 protects the user from scattered broken pieces of the workpiece and the end work tool 6, produced during operation such as grinding, polishing, cutting, etc. by the end work tool 6. The cover 7 is formed in a substantially semicircular shape so as to cover a part (for example, substantially half) of an outer periphery of the end work tool 6.

The operation switch 8 is operated by the user when the user rotates the end work tool 6. When the user presses the operation switch 8, the motor 11 is driven. When the motor 11 is driven, the end work tool 6 is rotationally driven.

The controller 13, when the user presses the operation switch 8, passes electric current to the motor 11 to rotate the motor 11.

[1-2. Heat Dissipation Structure of Electronic Component]

As shown in FIG. 2, the controller 13 accommodated in the housing 5 includes a printed circuit board (hereinafter, referred to as PCB) 21, and an electronic component 23 mounted on the PCB 21.

The electronic component 23 emits heat, and requires heat dissipation measures. The electronic component 23 is, for example, a switching element configured as an inverter which passes electric current to the motor 11. The switching element is, for example, a power MOSFET, but may be a different type of transistor. Also, the electronic component 23 may be an electronic component that emits heat, other than the switching element.

A metal plate 25 which serves as a heat sink is attached to a surface 23a of the electronic component 23 on a side opposite to a side facing the PCB 21. Specifically, the PCB 21 and the metal plate 25 are each fixed inside the housing 5 so that the surface 23a of the electronic component 23 on the side opposite to the side facing the PCB 21 is in contact with a surface of the metal plate 25. Thus, the metal plate 25 is thermally coupled to the electronic component 23. Accordingly, heat generated in the electronic component 23 is transferred to the metal plate 25. The metal plate 25 is made of, for example, aluminum, but may be made of a metal such as iron and copper. Also, there may be a member made of, for example, a thermally conductive elastic material between the electronic component 23 and the metal plate 25.

A graphite sheet 27 having high thermal conductivity is adhered to a surface (hereinafter, referred to as specific surface) 25b of the metal plate 25 on a side opposite to a side (that is, side facing the electronic component 23) 25a thermally coupled to the electronic component 23. The graphite sheet 27 is adhered to the specific surface 25b of the metal plate 25, for example, by a thermally conductive adhesive or an adhesive material such as a double-sided tape.

The metal plate 25 has thermal conductivity of about several hundreds [W/(m·K)]. On the other hand, the graphite sheet 27 has very high thermal conductivity of about 1600 [W/(m·K)], for example. Also, the graphite sheet 27 has a thickness of 25 [μm], for example. The graphite sheet 27 as such is disclosed, for example, in Japanese Unexamined Patent Application Publication No. 2015-216184.

[1-3. Effect]

According to the grinder 1 of the first embodiment having the heat dissipation structure as above, the following effect is produced.

Heat transferred from the electronic component 23 to the metal plate 25 is quickly transferred to a wide range of the metal plate 25 by the graphite sheet 27 adhered to the specific surface 25b of the metal plate 25. Therefore, heat dissipation effect of the electronic component 23 by the metal plate 25 is improved. Further, excellent heat radiation ability, that is, ability to release thermal energy as infrared, of the graphite sheet 27 further improves heat dissipation effect. Thus, when the same amount of heat is released, the metal plate 25 provided with graphite sheet 27 can have small thickness and area. As a result, it becomes easy to downsize the grinder 1.

### Second Embodiment

[2-1.]Difference from First Embodiment

Since the basic configuration of the second embodiment is the same as that of the first embodiment, the difference will be described below. The same reference numerals as those of the first embodiment indicate the same components, and the reference is made to the preceding description.

In the first embodiment, the entire one surface out of the two surfaces of the graphite sheet 27 is adhered to the specific surface 25b of the metal plate 25. That is, the graphite sheet 27 has the same plane shape as the specific surface 25b of the metal plate 25.

In contrast, in the grinder 1 of the second embodiment, the graphite sheet 27 has a different shape from that of the first embodiment.

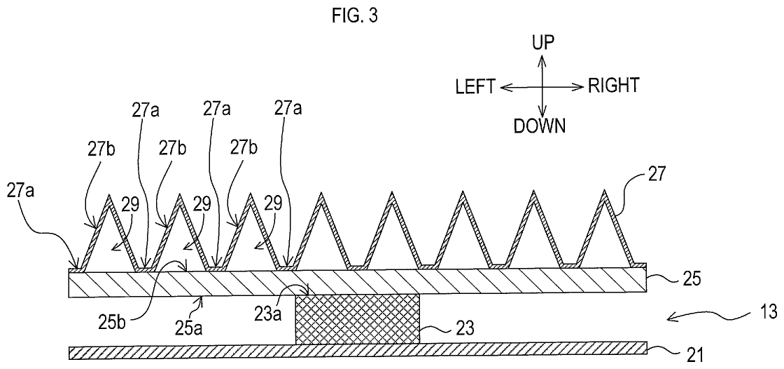

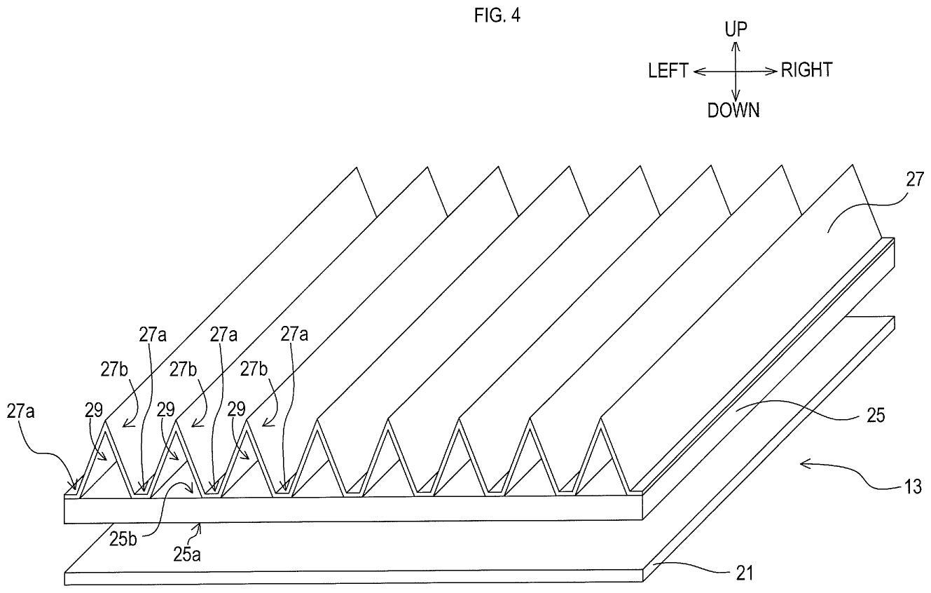

As shown in FIGS. 3 and 4, the graphite sheet 27 is adhered to the specific surface 25b of the metal plate 25 such that at least one (plural in FIGS. 3 and 4) adhering part 27a adhered to the specific surface 25b, and at least one (plural in FIGS. 3 and 4) non-adhering part 27b away from the specific surface 25b alternately appear in a specified direction. The specified direction is a left-right direction in FIGS. 3 and 4.

Hereinafter, in case of describing a plurality of adhering parts 27a and a plurality of non-adhering parts 27b, one of the adhering parts 27a and one of the non-adhering parts 27b will be described.

The non-adhering part 27b of the graphite sheet 27, together with the specific surface 25b of the metal plate 25, forms a tubular portion 29 through which the air is passable.

The non-adhering part 27b when seen in a direction perpendicular to the above-described specified direction and parallel to the specific surface 25b of the metal plate 25; that is, a cross section shown in FIG. 3, has a chevron shape. Specifically, the non-adhering part 27b when a side facing the metal plate 25 faces down has an inverted V shaped cross section. Thus, the tubular portion 29 has a triangular cylinder shape.

The cross section of the non-adhering part 27b when the side facing the metal plate 25 faces down may be a chevron shape, other than the inverted V shape, such as, for example, an inverted U shape or a semicircle. Also, the semicircle is not limited to a semicircle in a strict sense which bisects a perfect circle.

[2-2. Effect]

According to the second embodiment as above, area of contact between the graphite sheet 27 and the air can be increased. Therefore, heat dissipation effect of the electronic component 23 can be further improved.

### 3. Third Embodiment

3-1. Difference from Second Embodiment

Since the basic configuration of the third embodiment is the same as that of the first embodiment, the difference will be described below. The same reference numerals as those of the first and second embodiments indicate the same components, and the reference is made to the preceding description.

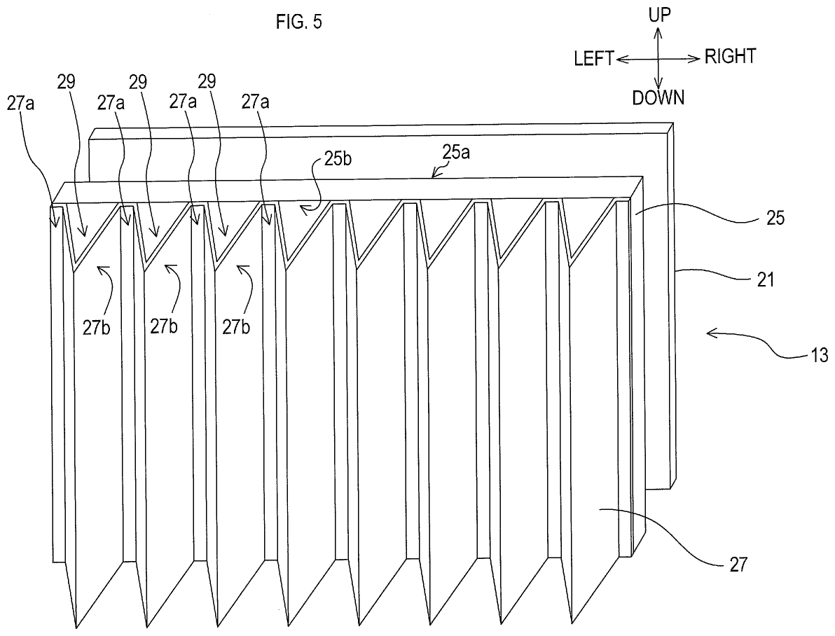

The second embodiment does not mention an installation direction of the metal plate 25 inside the grinder 1. In the grinder 1 of the third embodiment, as shown in FIG. 5, the metal plate 25 is installed inside the grinder 1 such that a longitudinal direction of the non-adhering part 27b is perpendicular to the ground. The longitudinal direction of the non-adhering part 27b is also a longitudinal direction of the tubular portion 29. In other words, in FIG. 5, each of the longitudinal directions of the non-adhering part 27b and the tubular portion 29 is an up-down direction. The downside in FIG. 5 is a side facing the ground, and the upside in FIG. 5 is a side facing above, perpendicularly to the ground.

Since the grinder 1 is a portable electric working machine, a posture of the grinder 1 when used is not necessarily constant. Among postures of the grinder 1 with reference to the ground, a posture considered most frequent when the grinder 1 is in use is referred to as “standard use posture”. The metal plate 25, when the grinder 1 is in the standard use posture, is installed inside the grinder 1 such that the longitudinal direction of the non-adhering part 27b is perpendicular to the ground. To give a specific example, the upside in FIG. 1 is a top side of the horizontally used grinder 1. A posture of the grinder 1 shown in FIG. 1 is the standard use posture. Thus, the metal plate 25 is fixed inside the grinder 1 so that the upside in FIG. 5 is the upside in FIG. 1.

On the other hand, if the electric working machine is a stationary electric working machine used in a fixed posture, then the metal plate 25 may be installed inside the electric working machine so that the longitudinal direction of the non-adhering part 27b is perpendicular to the ground when the electric working machine is in the above fixed posture.

[3-2. Effect]

According to the third embodiment as above, the longitudinal direction of the non-adhering part 27b is perpendicular to the ground. Therefore, the air flows along the non-adhering part 27b due to natural convection and passes through the tubular portion 29. Heat dissipation effect of the electronic component 23 can be further improved. Note that the term ‘perpendicular’ is not limited to ‘perpendicular’ in a strict sense, and may not be strictly ‘perpendicular’ as long as the same effect as the above is produced.

### 4. Fourth Embodiment

### 4-1. Difference from Second Embodiment

Since the basic configuration of the fourth embodiment is the same as that of the second embodiment, the difference will be described below. The same reference numerals as those of the first and second embodiments indicate the same components, and the reference is made to the preceding description.

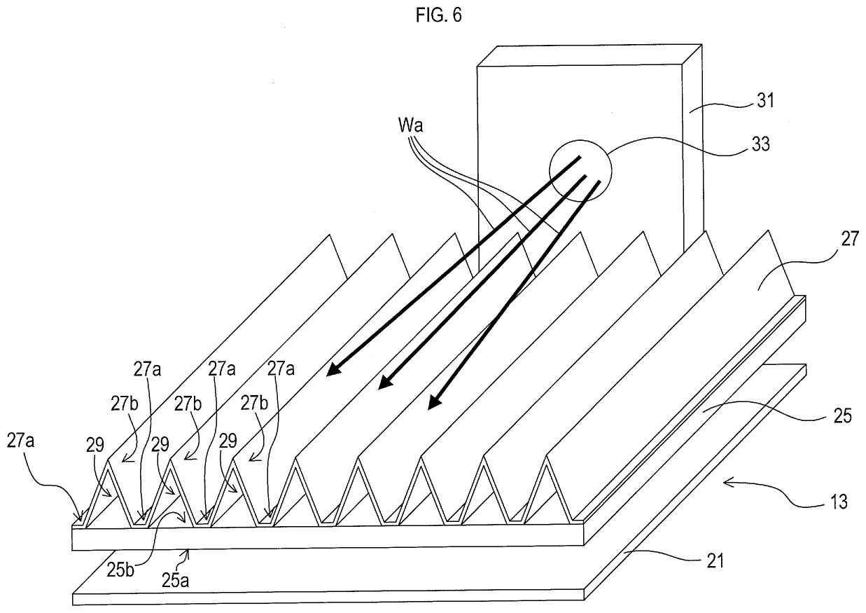

In comparison with the second embodiment, the grinder 1 of the fourth embodiment includes a blower 31 that blows wind to the graphite sheet 27, as shown in FIG. 6.

In the example of FIG. 6, the blower 31 is installed such that the wind blows from an air blowing port 33 of the blower 31 in the longitudinal direction of the non-adhering part 27b. An arrow Wa in FIG. 6 shows a direction of the wind blown out from the air blowing port 33.

In addition, the blower 31 is configured to generate wind by a built-in piezoelectric element. Specifically, the blower 31 is configured to vibrate a diaphragm by the piezoelectric element so as to discharge air from the air blowing port 33 which is an opening. The blower 31 as such is called a piezoelectric micro blower, which is disclosed, for example, in Japanese Unexamined Patent Application Publication No. 2012-77677 and No. 2013-50108.

[4-2. Effect]

According to the fourth embodiment configured as above, since the wind from the blower 31 hits the graphite sheet 27, heat dissipation effect of the electronic component 23 can be further improved. Also, the blower 31 is configured to generate wind by vibration of the piezoelectric element. Therefore, power consumption in the blower 31 can be reduced. Moreover, resistance of the blower 31 against vibration of the electric working machine can be strengthened.

As a variation, the blower 31 may be configured to blow wind, for example, by power of an electric motor. Even with the blower 31 as such, heat dissipation effect of the electronic component 23 can be improved.

### 5. Fifth Embodiment

[5-1. Difference from Fourth Embodiment]

Since the basic configuration of the fifth embodiment is the same as that of the fourth embodiment, the difference will be described below. The same reference numerals as those of the first and fourth embodiments indicate the same components, and the reference is made to the preceding description.

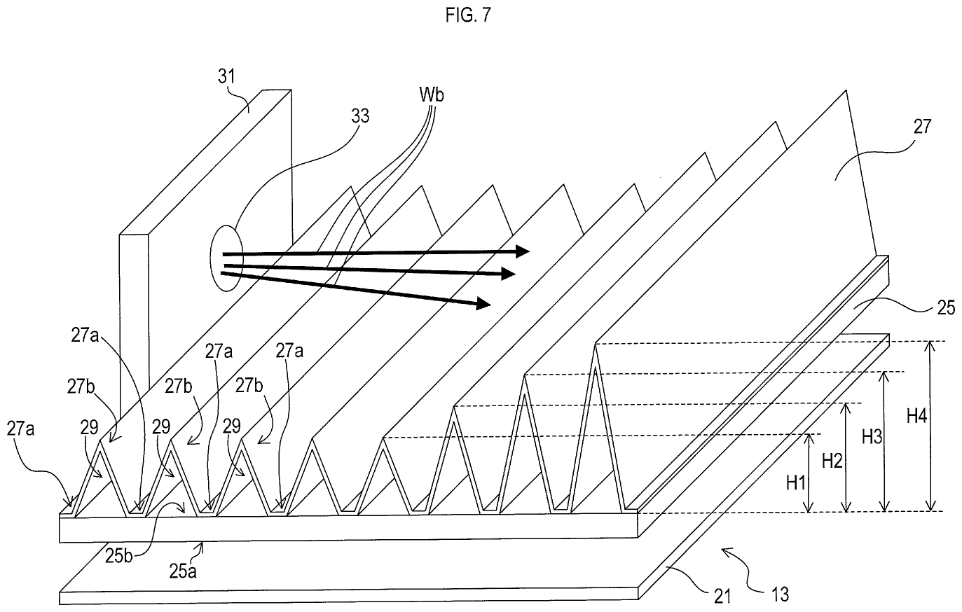

The grinder 1 of the fifth embodiment is different from that of the fourth embodiment in points <5-1-1>and <5-1-2>below.

<5-1-1>As shown in FIG. 7, the blower 31 is installed so that the wind from the air blowing port 33 blows in a direction perpendicular to the longitudinal direction of the non-adhering part 27b. An arrow Wb in FIG. 7 shows a direction of the wind blown out from the air blowing port 33.

<5-1-2>As shown in FIG. 7, the at least one non-adhering part 27b in the graphite sheet 27 has a larger height from the specific surface 25b as the non-adhering part 27b is farther from the blower 31. Specifically, in the plurality of non-adhering parts 27b in the graphite sheet 27, a non-adhering part 27b which is farther from the blower 31 has a larger height from the specific surface 25b. In FIGS. 7, H1 to H4 show heights of the fifth to eighth non-adhering parts 27b counted from the closest one of the plurality of non-adhering parts 27b to the blower 31. A magnitude relation of H1 to H4 is “H1<H2<H3<H4”.

[5-2. Effect]

Since the fifth embodiment includes the above-described feature of <5-1-2>, not only the non-adhering part 27b out of the plurality of non-adhering parts 27b close to the blower 31, but also the non-adhering part 27b far from the blower 31 can receive wind well. Therefore, heat dissipation effect of the electronic component 23 can be further improved.

Also in the fourth embodiment shown in FIG. 6 as a variation, the graphite sheet 27 may be configured so that the at least one non-adhering part 27b has a larger height from the specific surface 25b as the at least one non-adhering part 27b is farther from the blower 31. Specifically, in FIG. 6, as shown in a dash-dotted line, the graphite sheet 27 may be configured so that the non-adhering part 27b has a larger height from the specific surface 25b toward the front side of FIG. 6. Even in the configuration as such, the same effect as that in the fifth embodiment can be achieved. Also, the plurality of non-adhering parts 27b may be configured to have larger heights from the specific surface 25b toward the front side of FIG. 6.

### 6. Sixth Embodiment

[6-1. Difference from First Embodiment]

Since the basic configuration of the sixth embodiment is the same as that of the first embodiment, the difference will be described below. The same reference numerals as those of the first embodiment indicate the same components, and the reference is made to the preceding description.

In the first embodiment, the graphite sheet 27 is adhered to the single metal plate 25.

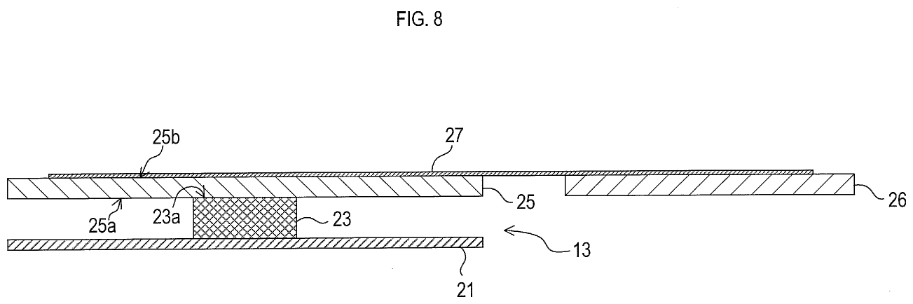

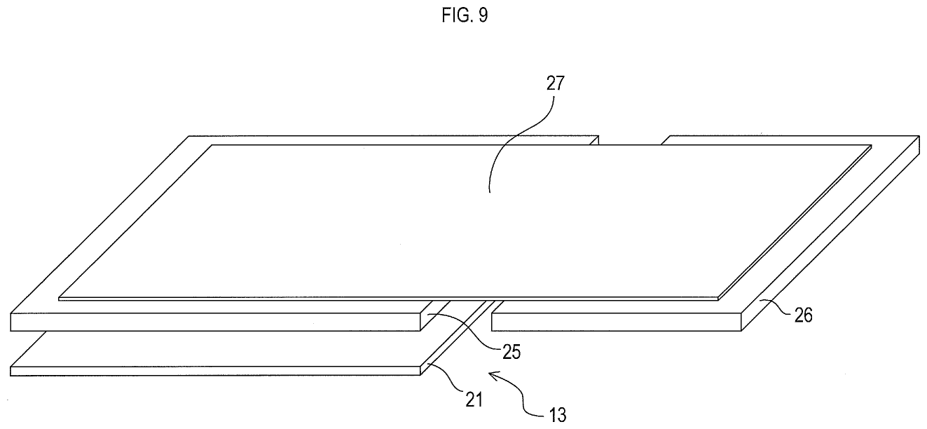

In contrast, in the grinder 1 of the sixth embodiment, as shown in FIGS. 8 and 9, the graphite sheet 27 is adhered both to the metal plate 25 and a metal plate 26, which is different from the metal plate 25, in a manner to extend over the both. For adhesion of the graphite sheet 27 to the metal plate 26 as well, an adhesive material such as, for example, a thermally conductive adhesive or a double-sided tape are used.

[6-2. Effect]

According to the sixth embodiment configured as above, heat from the electronic component 23 can be transferred from the metal plate 25 to the metal plate 26 via the graphite sheet 27. Therefore, heat dissipation effect of the electronic component 23 can be further improved. The metal plate 25 corresponds to one example of a first metal plate, and the metal plate 26 corresponds to one example of a second metal plate.

[7. Seventh Embodiment][7-1. Difference from First Embodiment]

Since the basic configuration of the seventh embodiment is the same as that of the first embodiment, the difference will be described below. The same reference numerals as those of the first embodiment indicate the same components, and the reference is made to the preceding description.

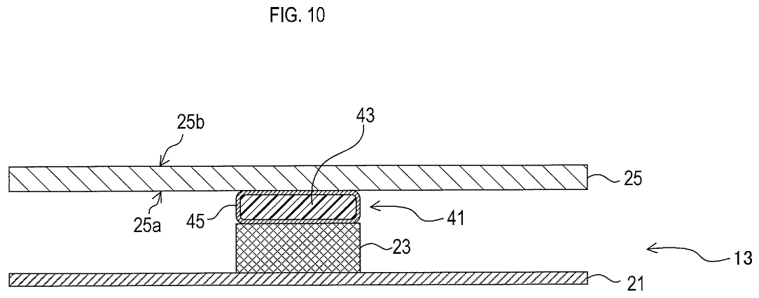

The grinder 1 of the seventh embodiment is different from that of the first embodiment in points <7-1-1>and <7-1-2>below.

<7-1-1>As shown in FIG. 10, a heat conduction member 41 that transmits heat from the electronic component 23 to the metal plate 25 is provided between the electronic component 23 and the metal plate 25.

The heat conduction member 41 includes a compressible deformable object 43 and a graphite sheet 45 wrapped around the object 43. In other words, the heat conduction member 41 is formed by wrapping the compressible deformable object 43 with the graphite sheet 45. Therefore, the heat conduction member 41 is elastically deformable, and a surface of the heat conduction member 41 is the graphite sheet 45. The compressible deformable object 43 may be made of, for example, silicone resin or synthetic rubber. The graphite sheet 45 is the same as the graphite sheet 27 of the first embodiment.

<7-1-2>As shown in FIG. 10, the graphite sheet 27 is not adhered to the specific surface 25b of the metal plate 25.

[7-2. Effect]

In the seventh embodiment, heat from the electronic component 23 is efficiently transferred to the metal plate 25 via the graphite sheet 45 configured as the heat conduction member 41. Therefore, heat dissipation effect of the electronic component 23 can be improved. Also, the shape of the heat conduction member 41, that is, an outer shape of the graphite sheet 45, can be compressed and deformed. Therefore, the heat conduction member 41 can thermally couple the electronic component 23 and the metal plate 25 while absorbing error in spacing, that is, assembling error, between the electronic component 23 and the metal plate 25. The compressible deformable object 43 may not limited to a solid but also, for example, a gas such as air or a h as water.

### [8. Other Embodiments]

At least part of the configurations of the above-described embodiments or the variations may be combined as appropriate.

[8-1]

For example, each of the first embodiment, the third embodiment and the sixth embodiment may include the blower 31 that blows wind to the graphite sheet 27, as in the fourth embodiment. In case that the third embodiment includes the blower 31, the blower 31 may be configured such that the wind from the air blowing port 33 blows from the downside to the upside in FIG. 5.

[8-2]

For example, in each of the second embodiment to the fifth embodiment, the graphite sheet 27 may extend from the metal plate 25, and an extended portion from the graphite sheet 27 may be adhered to a surface of an additional metal plate 26, as in the sixth embodiment.

[8-3]

The configuration of the seventh embodiment may be combined with any of the configurations of the first to sixth embodiment. For example, in the seventh embodiment, the graphite sheet 27 similar to that of the first embodiment, or the graphite sheet 27 similar to that of the second embodiment may be adhered to the specific surface 25b of the metal plate 25.

[8-4]

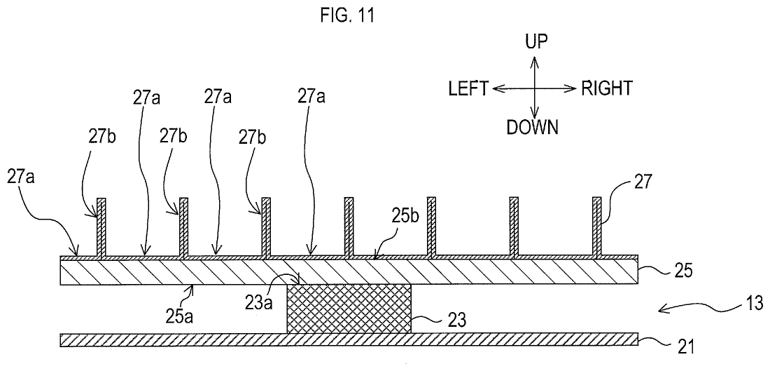

For example, as a variation of the second embodiment, as shown in FIG. 11, the non-adhering part 27a of the graphite sheet 27 may not form the tubular portion 29. In the example of FIG. 11, the non-adhering part 27b has an I-shaped cross section. In this case, in the graphite sheet 27, the non-adhering parts 27b between the adhering parts 27a may be adhered to each other. Also, the variation as in FIG. 11 can be applied to other embodiments.

[8-5. Others]

The embodiments of the present disclosure have been described in the above. The present disclosure is not limited to the above-described embodiments, and can be practiced in various modes.

For example, the electric working machine may be an electric hammer, an electric hammer drill, an electric drill, an electric driver, an electric wrench, an electric reciprocating saw, an electric jigsaw, an electric cutter, an electric chain saw, an electric plane, an electric circular saw, an electric nailer including an electric tacker, an electric hedge trimmer, an electric lawn mower, an electric grass trimmer, an electric trimmer, an electric cleaner, an electric blower, and so on.

Also, a plurality of functions achieved by a single component in the above-described embodiments may be achieved by a plurality of components, or a single function achieved by a single component may be achieved by a plurality of components. Also, a plurality of functions achieved by a plurality of components may be achieved by a single component, or a single function achieved by a plurality of components may be achieved by a single component. Moreover, some of the configurations of any of the above-described embodiments may be omitted. Further, at least part of the configuration of any of the above-described embodiments may be added or substituted to the configuration of another embodiment. Any aspects included in the technical idea specified by the language as set forth in the appended claims are embodiments of the present disclosure. The present disclosure can be implemented in various forms, such as a dissipation method of an electric working machine.

1. An electric working machine comprising:
an electronic component that emits heat;
a metal plate thermally coupled to the electronic component; and
a graphite sheet adhered to a specific surface which is a surface of the metal plate opposite to a surface thermally coupled to the electronic component.

2. The electric working machine according to claim 1, wherein
the graphite sheet is adhered to the specific surface such that at least one adhering part adhered to the specific surface and at least one non-adhering part away from the specific surface alternately appear in a specified direction.

3. The electric working machine according to claim 2, wherein
each of the at least one non-adhering part, together with the specific surface, forms a tubular portion which is away from the specific surface and through which air is passable.

4. The electric working machine according to claim 2, wherein
the metal plate is arranged so that a longitudinal direction of each of the at least one non-adhering part is perpendicular to the ground.

5. The electric working machine according to claim 2, further comprising:
a blower that blows wind to the graphite sheet.

6. The electric working machine according to claim 5, wherein
the at least one non-adhering part in the graphite sheet has a larger height from the specific surface, as the at least one non-adhering part is farther from the blower.

7. The electric working machine according to claim 1 further comprising:
a blower that blows wind to the graphite sheet.

8. The electric working machine according to claim 5, wherein
the blower is configured to generate wind by a piezoelectric element.

9. The electric working machine according to claim 1, wherein
the metal plate is a first metal plate,
the electric working machine further includes a second metal plate different from the first metal plate, and
the graphite sheet is adhered to the first metal plate and the second metal plate, in a manner to extend over the both plates.

10. An electric working machine comprising:
an electronic component that emits heat;
a metal plate; and
a heat conduction member provided between the electronic component and the metal plate, the heat conduction member transmitting heat from the electronic component to the metal plate,
the heat conduction member including:
a compressible deformable object; and a graphite sheet wrapped around the object.
